(19) United States
(12) Patent Application Publication
(10) Pub. No.: US 2006/0231825 A1
(43) Pub. Date: Oct. 19, 2006

(54) Use of quasi-one-dimensional transition metal ternary compounds and quasi-one-dimensional transition metal chacogenide compounds as electron emitters

(75) Inventors: Vincenc Nemanic, Ljubljana (SI); Marko Zumer, Ljubljana (SI); Ales Mrzel, Ljubljana (SI); Maja Remskar, Grosuplje (SI); Dragan D. Mihailovic, Ljubljana (SI)

Correspondence Address: CONNOLLY BOVE LODGE & HUTZ LLP, SUITE 800, 1990 M STREET NW, WASHINGTON, DC, 20036-3425, US

(73) Assignee: INSTITUT "JOSEF STEFAN", LJUBLJANA (SI)

(21) Appl. No.: 10/522,740

(22) PCT Filed: Jul. 23, 2003
(86) PCT No.: PCT/SI03/00027

§ 371 Date: Feb. 17, 2006

(30) Foreign Application Priority Data
Aug. 2, 2002 (SI) P-200200189

(51) Int. Cl. H01L 29/06; H01L 29/12

(52) U.S. Cl. 257/10

(57) ABSTRACT

The present invention pertains to the use of quasi-one-dimensional transition metal ternary compounds MₓH_{y}Ha_{z} (where M is a transition metal Mo, W, Ta, Nb; H is sulfur (S), selenium (Se), tellurium (Te); Ha is iodine (I)) and of doped quasi-one-dimensional transition metal ternary compounds MₓH_{y}Ha_{z}, (where M=Ta, Ti, Nb; H is sulfur (S), selenium (Se), tellurium (Te); Ha is iodine (I)) with elements of group 1b (silver) (Ag), gold (Au), or copper (Cu)) as electron emitters under the influence of an external electric field. The percentage of quasi-one-dimensional transition metal ternary compounds doped with elements of group 1b in the active material ranges from 0.01 to 99.9 the rest consisting of additives in the form of conducting, non-conducting or semi-conducting compounds or composites. Electron emission takes place at a pressure below 1 mbar.

The object of the invention is the use of quasi-one-dimensional transition metal ternary compounds MₓH_{y}Ha_{z} (where M is a transition metal Mo, W, Ta, Nb; H is sulfur (S), selenium (Se), tellurium (Te); Ha is iodine (I)) and of doped quasi-one-dimensional transition metal ternary compounds MₓH_{y}Ha_{z} (where M=Ta, Ti, Nb; H is sulfur (S), selenium (Se), tellurium (Te); Ha is iodine (I)) with elements of group 1b (silver (Ag), gold (Au), copper (Cu)) as electron emitters under the influence of an external electric field, i.e. for cold electron emission (“cold cathode”).

Electron emitters are used in various commercially available devices. Conventional emitters, used in cathode tubes, are usually made of tungsten wire or other materials with a low surface work function that emit electrons when heated (Shan I, Physics Word, 45, June (1997). Lately, vast research is being conducted on the so-called cold electron emitters which release electrons due to electric field intensity. Known devices based on cold electron emission may essentially assume two geometric forms. The first form consists in very sharp electron-emitting tips arranged in a specific configuration, this being achieved through elaborate photolithographic techniques. Said tips are generally made of silicon, molybdenum or tungsten, although recently, considerable progress has been made in the use of diamond powder with a specific lattice configuration, or a coating of such diamond powder or of similarly structured carbon on other microtips (Kumar N. et al., U.S. Pat. No. 5,199,918 of Apr. 6, 1993). Additionally, it is possible to use microtips shaped as thin wires and scales of various materials including carbon (Q. Wang et al., App. Phys. Lett. 70, 24, pp. 3308 (1997). With the first method, highly complex lithographic techniques are required to fabricate the tips. Moreover, tips not made of diamond have a relatively short life span due to resistive heating, which gives rise to tip erosion. Both problems can be overcome by making use of diamond microtips, for proper operation, however, high anode voltage is required.

According to the second method,. the device based on electron emission relies on low or negative electron affinity of the surface which is usually made of diamond or of diamond-like carbon (Kumar N. et al., U.S. Pat. No. 5,341,063 of Aug. 23, 1994; Valone S. N. et al., U.S. Pat. No. 5,602,439 of Feb. 2, 1997). The second method likewise requires a high anode voltage which rather complicates the operation of the device. To improve functionality, diamond or diamond-like carbon with various lattice-structure defects have been employed (Jaskie J. E. et al., U.S. Pat. No. 5,619,092 of Apr. 8, 1997) and some other improvements have been introduced (Habermann et al., J. Vac. Sci. Tech. B16, p. 693, 1998; Patterson D. E. et al., Mat. Res. Soc. Symp. Proc. 509, 1998).

In recent years new nanomaterials, particularly carbon and BₓC_{y}N_{z} nanotubes have been found to constitute a promising source for electron emission (Zettl A. et al., U.S. Pat. No. 6,057,637 of May 2, 2000). Due to the shape of these nanomaterials as such the stability of the cathode current is good as opposed to metal tips which lose sharpness over time, and work voltages are lower as compared to diamond powder. There are still several problems hampering their application, however—primarily the non-homogeneity of the material due to the uncontrolled synthesis and the problem of the disposition of the nanotubes with respect to the substrate (De Heer W. A. et al., Science 270, 1179 (1995)), although there have been attempts to reduce these disadvantages with new methods of synthesis.

Therefore, the following drawbacks are exhibited by conventional cold electron emitters: the wear and tear of the metal tip, the elaborate and costly tip fabrication technique wherein a diamond is required, the high anode. voltage, and, for nanomaterials, the low definition or reproducibility of the emitters.

It is the object of the present invention to disclose and utilize such materials for fabricating cold electron emitters that will allow emitters to function in a stable and lasting manner, to be readily manufactured, and to operate at low anode voltages.

According to the invention, said object is achieved by employing quasi-one-dimensional transition metal ternary compounds and quasi-one-dimensional transition metal chalcogenide compounds as electron emitters, as defined by the independent patent claims.

The invention shall now be described with reference to two preferred embodiments thereof and illustrated in the accompanying drawings, in which:

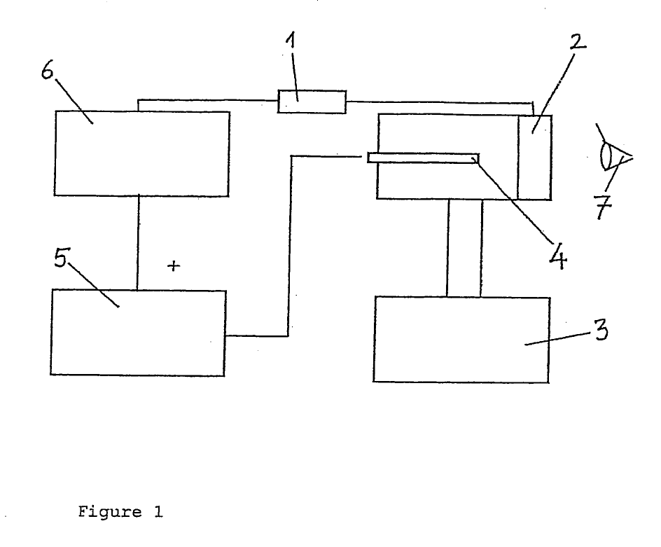

FIG. 1 schematically shows a measuring cell for measuring cold emission;

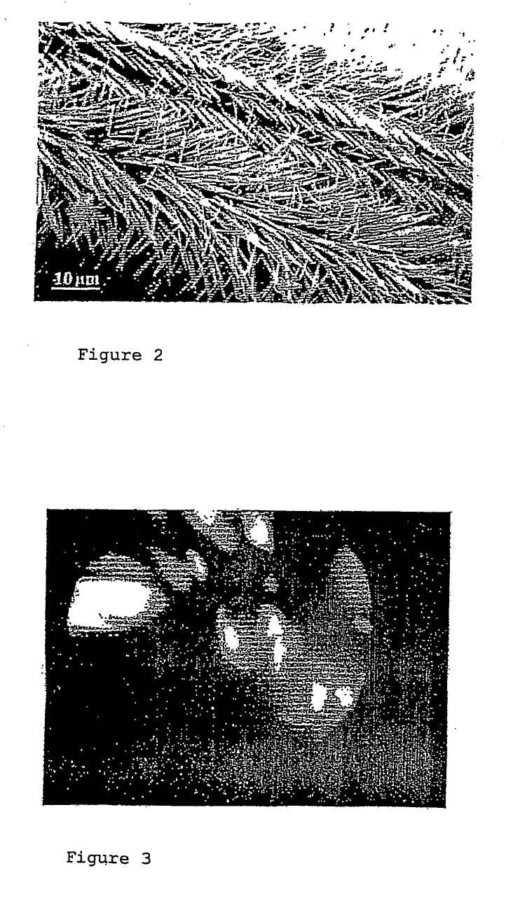

FIG. 2 shows the material made of bundles of MoS_{2-y}Iₓ . nanotubes which is employed as the electron emission source in an external electric field;

FIG. 3 is a typical picture on the screen created by electrons emitted from bundles of MoS_{2-y}I_{,} nanotubes;

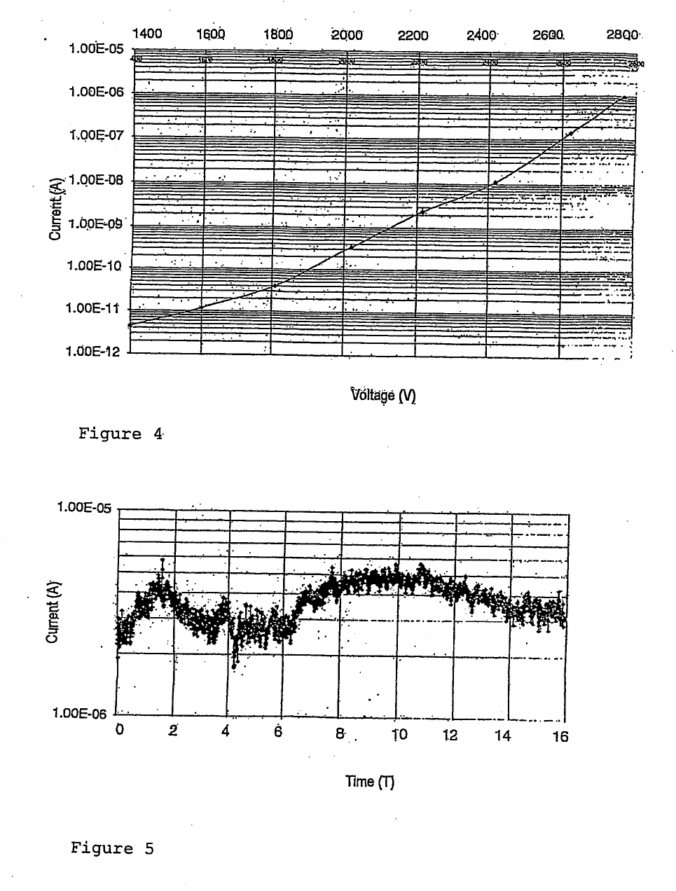

FIG. 4 is a diagram showing the voltage dependence of the emission current from MoS_{2-y}Iₓ;

FIG. 5 shows the time stability of the emission current of bundles of MoS_{2-y}Iₓnanotubes;

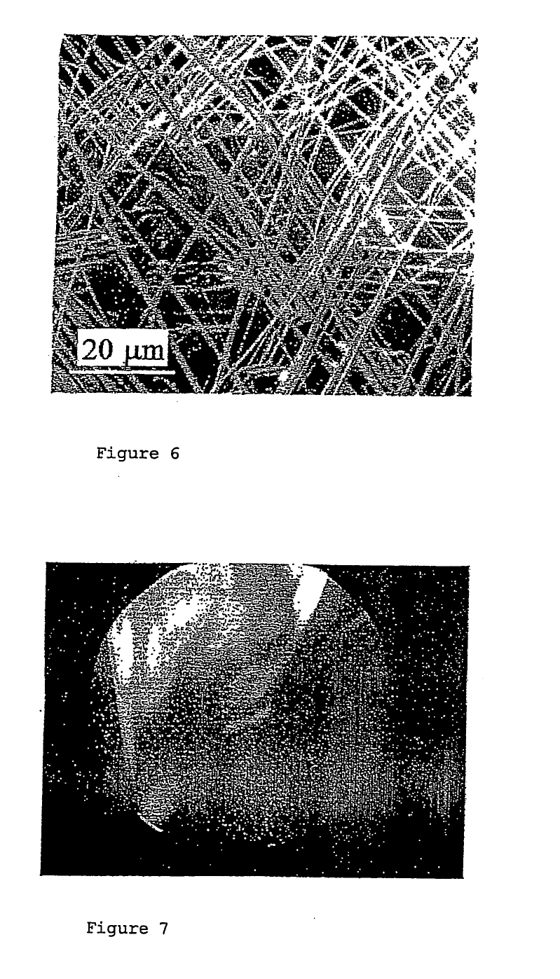

FIG. 6 shows the material made of Agₓ(NbS₄)₄I_{y} used as electron emission source in an external electric field;

FIG. 7 is a typical picture on the screen created by electrons emitted from Agₓ(NbS₄)₄I_{y};

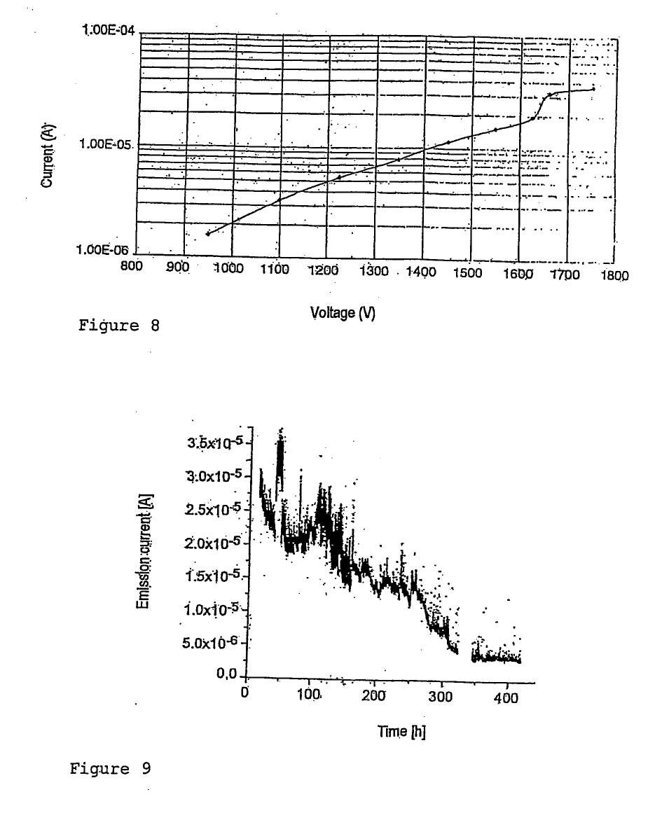

FIG. 8 is a diagram showing the voltage dependence of the emission current from Agₓ(NbS₄)₄I_{y};

FIG. 9 shows the time stability of the emission current from Agₓ(NbS₄)₄I_{y.}

The present invention relates to the use of quasi-one-dimensional transition metal ternary compounds MₓH_{y}Ha_{z} (where M is a transition metal Mo, W, Ta, Nb; H is sulfur (S), selenium (Se), tellurium (Te); Ha is iodine (I)) and of doped quasi-one-dimensional transition metal ternary compounds MₓH_{y}Ha_{z} (where M=Ta, Ti, Nb; H is sulfur (S), selenium (Se), tellurium (Te); Ha is iodine (I)) with elements of group 1b (silver (Ag), gold (Au), or copper (Cu)) as electron emitters under the influence of an external electric field. The percentage of quasi-one-dimensional transition metal ternary compounds and/or doped quasi-one-dimensional transition metal ternary compounds doped with elements of group 1b in the active material ranges from 0.01 to 99.9%, the rest consisting of additives in the form of conducting, non-conducting or semi-conducting compounds or composites.

In accordance with the invention said materials are employed as the cathode emitter material in devices based on electron emission under the influence of an external electric field. Electron emission takes place at a pressure below 1 mbar.

First Embodiment

Use of bundles of MoS_{2-y}Iₓ , nanotubes for electron emission Bundles of MoS_{2-y}Iₓ , nanotubes are used as cold emitter. The emission characteristic of the bundles of MoS_{2-y}Iₓ , nanotubes (that is, the emission current I in dependence of the voltage U) employed as the cold electron emitter (cathode) is measured in high vacuum. The measurement of cold emission in a measuring cell of the type used in our research is schematically depicted in FIG. 1. It is based on a glass vacuum vessel with two metal electrodes. The measuring cell consists of a protective resistor 1, an anode 2 with a screen, an ion-getter pump 3, a nano-emitter 4, a voltage source 5, and an ammeter 6. The protection resistor is a 33 MOhm carbon (graphite-ceramic) resistor. The anode 2 is the positive electrode which at the same time serves as the screen in the FEM, thus allowing the pattern produced by the emitted electrons to be observed, said screen consisting of a 5-micrometers-thick layer of granular luminescent substance (the average grain size being 1.2 micrometers). The luminescent substance is labeled P-43 and its chemical structure is Gd₂O₂:Tb, coated with an aluminum evaporation layer 90 nm thick. The ion-getter pump 3 is a vacuum pump based on discharge in a gas and diffusion. For the measurement, a Leybold Heraeus IZ30 pump was used. The nano-emitter 4 is the negative electrode, namely the cathode in the FEM. In this embodiment the nano-emitter consists of bundles of MOS_{2-y}Iₓ nanotubes. Both the nano-emitter 4 and the anode 2 are in a high vacuum. As voltage supply 5, a precision stabilized rectifier Thorn EMI, model PM 28B was used. The anode voltage was varied in the range of 600 to 2800 V. The current was measured with a Keithley model 485 picoammeter 5. The eye symbol designates the direction of observation of the emitted light.

The bundles of MoS_{2-y}Iₓ nanotubes were attached on the 0.1 mm thick Ni sheet with silver paste which ensures good electrical contact with the conducting substrate. The brand used was SPI Flash dry, 4999AB paste, supplied by SPI Supplies for the preparation of samples for scanning electron microscopy. A sample of bundles of MoS_{2-y}Iₓ nanotubes with a mass of approx. 3 mg is shown in FIG. 2. It was applied on the tip of the metal conductor by means of the same paste, at a distance a from the anode. Prior to measuring the emission, the sample was pumped for several hours at room temperature, and subsequently for another 3 hours at 200° C. The current-voltage characteristic and the emission stability of the thus prepared sample were measured at room temperature. The first tests were performed at a distance a=20±1 mm, wherein it was possible to visually observe the emission pattern at high currents. With this measurement it was confirmed that the measured current is definitely a consequence of cold emission through vacuum and not a consequence of a leaking insulation. The typical picture on the screen created by electrons emitted from the bundles of MoS_{2-y}Iₓ , nanotubes is shown in FIG. 3. The voltage was 5 kV. The subsequent measurements of the voltage dependence of the current and of the time dependence of the current were carried out at a distance a=5±1 mm. The anode voltage was varied in the range of 600 to 2800 V. The current was measured with a picoammeter 6.

The readout was recorded with a personal computer 2.8 times per second. At the maximum voltage of the power supply 3000 V the voltage on the emitter was 2770 V, whereas the emission current reached the value of 1 μA as, shown in FIG. 4. The measurement of the time stability of the emission current over a period of 16 hours showed the emission of electrons from the bundles of MoS_{2-y}Iₓ, nanotubes to be relatively stable, FIG. 5.

Second Embodiment

Use of Agₓ(NbS₄)₄I_{y} for electron emission

As cold emitter Agₓ(NbS₄)₄I_{y} is used. The emission characteristic of Agₓ(NbS₄)₄I_{y} (that is, the emission current I in dependence of the voltage U) employed as the cold electron emitter is measured in high vacuum. The measurement of cold emission as used in our research is schematically shown in FIG. 1 and is analogous to the first embodiment. 4 mg of Agₓ(NbS₄)₄I_{y} as shown in FIG. 6 were first attached to a 0.1 mm Ni foil by means of a conducting binder .(SPI, silver paste for SEM), whereupon the foil was glued on the tip of the metal conductor using the same adhesive, at a distance a from the anode 2. Prior to measuring the emission, the sample was pumped for several hours in the FEM at room temperature, and subsequently for another 3 hours at 2000° C. The current-voltage characteristic and the emission stability of the thus prepared sample were measured at room temperature. The first tests were performed at a distance a=20±1 mm, where it was possible to visually observe the emission pattern at high currents. With this measurement it was confirmed that the measured current is definitely a consequence of cold emission through vacuum and not a consequence of a leaking insulation. The typical picture on the screen created by electrons emitted from the bundles of Agₓ(NbS₄)₄I_{y} nanotubes is shown in FIG. 7.

The subsequent measurements of the voltage dependence of the current and of the time dependence of the current were carried out at a distance a=5±1 mm. The anode voltage was varied in the range of 600 to 2800 V, as can be seen in FIG. 8. The current was measured with a picoammeter 6. The readout was recorded with a personal computer 2.8 times per second. At 2800 V the voltage on the emitter was 1750 V, whereas the emission current reached the value of 30 μA. The measurement of the time stability of the emission current over a period of 330 hours showed the emission of electrons from the Agₓ(NbS₄)₄I_{y} material to be relatively stable.

Materials based on quasi-one-dimensional transition metal ternary compounds MₓH_{y}Ha_{z} (where M is a transition metal Mo, W, Ta, Nb; H is sulfur (S), selenium (Se), tellurium (Te); Ha is iodine (I)) and/or doped quasi-one-dimensional transition metal ternary compounds MₓH_{y}H_{z} (where M=Ta, Ti, Nb; H is sulfur (S), selenium (Se), tellurium (Te); Ha is iodine (I)) doped with elements of group 1b (silver (Ag), gold (Au), or copper (Cu)) are thus used as electron emitters under the influence of an external electric field. The percentage of quasi-one-dimensional transition metal ternary compounds and/or doped quasi-one-dimensional transition metal ternary compounds doped with elements of group 1b in the active material ranges from 0.01 to 99.9%, the rest consisting of additives in the form of conducting, non-conducting or semi-conducting compounds or composites. Electron emission takes place at a pressure below 1 mbar.

It is to be understood that electron emitters under the influence of an external electric field that are made of materials based on quasi-one-dimensional transition metal ternary compounds MₓH_{y}Ha_{z} (where M is a transition metal Mo, W, Ta, Nb; H is sulfur (S), selenium (Se), tellurium (Te); Ha is iodine (I)) and/or doped quasi-one-dimensional transition metal ternary compounds MₓH_{y}Ha_{z} (where M=Ta, Ti, Nb; H is sulfur (S), selenium (Se), tellurium (Te); Ha is iodine (I)) doped with elements of group 1b (silver (Ag), gold (Au), or copper (Cu)), wherein the percentage of quasi-one-dimensional transition metal ternary compounds and/or doped quasi-one-dimensional transition metal ternary compounds doped with elements of group 1b in the active material ranges from 0.01 to 99.9%, the rest consisting of additives in the form of conducting, non-conducting or semi-conducting compounds or composites are likewise considered to be within the scope of the present invention.

1. Use of materials based on quasi-one-dimensional transition metal ternary compounds MₓH_{y}Ha_{z} (where M is a transition metal Mo, W, Ta, Nb; H is sulfur (S), selenium (Se), tellurium (Te); Ha is iodine (I)) and/or doped quasi-one-dimensional transition metal ternary compounds MₓH_{y}Ha_{z} (where M=Ta, Ti, Nb; H is sulfur (S), selenium (Se), tellurium (Te); Ha is iodine (I)) doped with elements of group 1b (silver (Ag), gold (Au), or copper (Cu)) as electron emitters under the influence of an external electric field.

2. Use of materials according to claim 1, characterized in that the percentage of quasi-one-dimensional transition metal ternary compounds and/or doped quasi-one-dimensional transition metal ternary compounds doped with elements of group 1b in the active material ranges from 0.01 to 99.9%, the rest consisting of additives in the form of conducting, non-conducting or semi-conducting compounds or composites.

3. Use of materials according to claim 1, characterized in that electron emission takes place at a pressure below 1 mbar.

4. Electron emitters under the influence of an external electric field, characterized in that they are made of materials based on quasi-one-dimensional transition metal ternary compounds MₓH_{y}Ha_{z} . (where M is a transition metal Mo, W, Ta, Nb; H is sulfur (S), selenium (Se), tellurium (Te); Ha is iodine (I)) and/or doped quasi-one-dimensional transition metal ternary compounds MₓH_{y}Ha_{z} (where M=Ta, Ti, Nb; H is sulfur (S), selenium (Se), tellurium (Te); Ha is iodine (I)) doped with elements of group 1b (silver (Ag), gold (Au), or copper (Cu)).

5. Electron emitters according to claim 4, characterized in that the percentage in such materials of quasi-one-dimensional transition metal ternary compounds and/or doped quasi-one-dimensional transition metal ternary compounds doped with elements of group 1b in the active material ranges from 0.01 to 99.9%, the rest consisting of additives in the form of conducting, non-conducting or semi-conducting compounds or composites.

6. Electron emitters according to claim 4, characterized in that electron emission takes place at a pressure below 1 mbar.

7. Use of materials according to claim 2, characterized in that electron emission takes place at a pressure below 1 mbar.

8. Electron emitters according to claim 5, characterized in that electron emission takes place at a pressure below 1 mbar.
